(19) United States
(12) Patent Application Publication
(10) Pub. No.: US 2007/0246790 A1
(43) Pub. Date: Oct. 25, 2007

(54) Transistor process using a double-epitaxial layer for reduced capacitance

(75) Inventors: Raymond Zinn, Atherton, CA (US); Martin Alter, Los Altos, CA (US)

Correspondence Address: PATENT LAW GROUP LLP, 2635 NORTH FIRST STREET, SUITE 223, SAN JOSE, CA, 95134, US

(73) Assignee: Micrel, Inc.

(21) Appl. No.: 11/408,339

(22) Filed: Apr. 20, 2006

(51) Int. Cl. H01L 23/58

(52) U.S. Cl. 257/492

(57) ABSTRACT

In a method to form a DMOS or bipolar transistor, two epitaxial silicon layers are grown over a silicon substrate instead of the typical one low-resistivity epitaxial layer. The bottom epitaxial layer has a relatively high resistivity of, for example 10 ohms-cm, while the upper epitaxial layer, acting as a drift region, may have a conventional low resistivity such as 3 ohms-cm. The bottom epi layer, being less doped than the upper epi layer, causes a wider and deeper depletion region to occur for a given drain or collector voltage, as compared to a depletion region where the entire epitaxial layer is formed of the upper epitaxial layer composition. Therefore, the parasitic capacitor's depletion region will be wider and deeper when employing the bottom epitaxial layer. The wider and deeper depletion region in the lower epitaxial layer lowers the overall parasitic capacitance value. This improves the switching speed of the transistor. The technique preferably requires no additional process steps so adds no cost to the fabrication process.

### FIELD OF THE INVENTION

This invention relates to a process for forming transistors, including DMOS and bipolar transistors, and in particular to a process for lowering a capacitance of the transistor to enable faster operation.

### BACKGROUND

Lateral MOSFETS and bipolar transistors are well known. FIG. 1 illustrates a typical n-channel DMOS transistor 10. An n-type epitaxial layer 12 is grown over a p-type silicon substrate 14. A p-body region 16 is then formed in the n-epi layer 12. A gate 18 is formed over and insulated from an edge of the body region 16, where the portion of the body region under the gate acts as a channel region. A p+ body contact region 20 and an n+ source region 22 are formed in the surface of the body region 16. The body contact region 20 and substrate 14 are typically connected to ground. An n+ drain region 24 is formed in the n-epi layer 12 separated from the body region 16. The drain region 24 is typically connected to an output pin of the IC package or to an internal circuit node. The source region 22 is typically connected to ground. Oxide regions 26 may be used to align the doped regions.

When a positive voltage above the threshold voltage is applied to the gate, the p− body inverts under the gate, and a current flows between the source and drain through the n-epi layer and the n-channel under the gate.

The n-epi layer between the drain and the body acts as a drift region, separating the drain from the body and source. The epi layer in the drift region depletes to some extent when the transistor is off, which enables the silicon to support the high voltage on the drain. It is important for the resistivity of the n-epi to be low (e.g., 3 ohms-cm) so there is low on-resistance. The n-epi layer cannot be too heavily doped or else the depletion region will be small and the breakdown voltage will be too low. Thus, there is a tradeoff between on-resistance and breakdown voltage, and the resistivity (controlled by the doping level) of the n-epi layer is optimized.

FIG. 1 also shows p+ isolation regions 28A and 28B surrounding the DMOS transistor and a p+ region 28C between the p substrate 14 and the p-body region 16.

There are parasitic capacitances (Cp) between the n+ drain region 24 and the various p regions and p substrate. These parasitic capacitances delay the turn on and turn off of the DMOS transistor. The parasitic capacitor “electrodes” are the drain region and the p-regions/substrate. The capacitance of the depleted n-epi layer when the transistor is in its off state is related to the area of the capacitor and the thickness of the depletion region by the formula Cⱼ=K_{Si}ε₀A/X, where K_{Si} is the dielectric constant of silicon, ε₀ is the permittivity of free space, A is the area, and X is the width of the depletion region.

A similar capacitance problem exists with bipolar transistors. The parasitic capacitances between the collector and the other regions/substrate slow the switching speed.

What is needed is a simple technique to reduce the capacitance of DMOS and bipolar transistors to improve their switching speed.

### SUMMARY

A technique is described herein that reduces the parasitic capacitance of transistors while not adversely affecting other performance characteristics of the transistor. The technique requires no additional process steps so adds no cost to the fabrication process.

Prior art lateral DMOS transistors require a low resistivity epitaxial layer through which current flows to achieve a low on-resistance. However, the doping level of the epitaxial layer is optimized to also provide the desired breakdown voltage between the body and the drain. Therefore, so as to not adversely affect the performance of the prior art transistors, the upper portion of the epitaxial layer that affects on-resistance and breakdown voltage is not changed by the present invention.

In the process of the present invention, two epitaxial layers are grown over the substrate instead of the typical single low-resistivity epitaxial layer. The bottom epitaxial layer has a trivial effect on the on-resistance since the majority of current flows near the surface through the upper epitaxial layer. The bottom epitaxial layer has a relatively high resistivity of, for example 10 ohms-cm, while the upper epitaxial layer may have the conventional low resistivity such as 3 ohms-cm. Under the same conditions, an epitaxial layer with a resistivity of 10 ohms-cm depletes more than an epitaxial layer with a resistivity of 3 ohms-cm, since the more resistive epitaxial layer has a lower dopant density. Therefore, the parasitic capacitor's depletion width between the drain “electrode” and substrate “electrode” will be wider when employing the bottom epitaxial layer and, therefore, will result in a lower parasitic capacitance value. This improves the switching speed of the transistor.

The bottom epitaxial layer also increases the width of the depletion layer between the drain and other “bottom” regions, such as the p+ isolation regions.

The combined thickness of the bottom epitaxial layer and the upper epitaxial layer may be the same as the thickness of a prior art single epitaxial layer in a transistor, while still gaining the benefits of the invention, so no additional growth time is required.

Since the bottom epitaxial layer and upper epitaxial layer are formed using the same process but with different flow rates of the n-type doping gas, the bottom epitaxial layer may be formed without adding time or expense to the fabrication process. While forming the epitaxial layers, the n-doping gas flow rate is simply increased when the upper epitaxial layer is to be formed.

The above process decreases the capacitance for MOSFET and bipolar lateral or vertical transistors.

### BRIEF DESCRIPTION OF THE DRAWINGS

FIG. 1 is a cross-sectional view of a prior art lateral DMOS transistor.

FIG. 2 is a cross-sectional view of the transistor of FIG. 1 but employing a double-epi layer, for a reduced drain-to-substrate capacitance, in accordance with one embodiment of the invention.

FIG. 3 is a flowchart showing basic steps used to form the DMOS transistor of FIG. 2.

FIG. 4 is a chart showing the capacitances of a 3 ohm-cm n-epi layer and a 10 ohm-cm epi layer with various voltages across the epi layers, illustrating that the 10 ohm-cm epi layer has a lower capacitance value per square centimeter.

FIG. 5 is a cross-sectional view of a vertical bipolar transistor employing a double-epi layer, for a reduced collector-to-substrate capacitance, in accordance with one embodiment of the invention.

FIG. 6 is a flowchart showing basic steps used to form the bipolar transistor of FIG. 5.

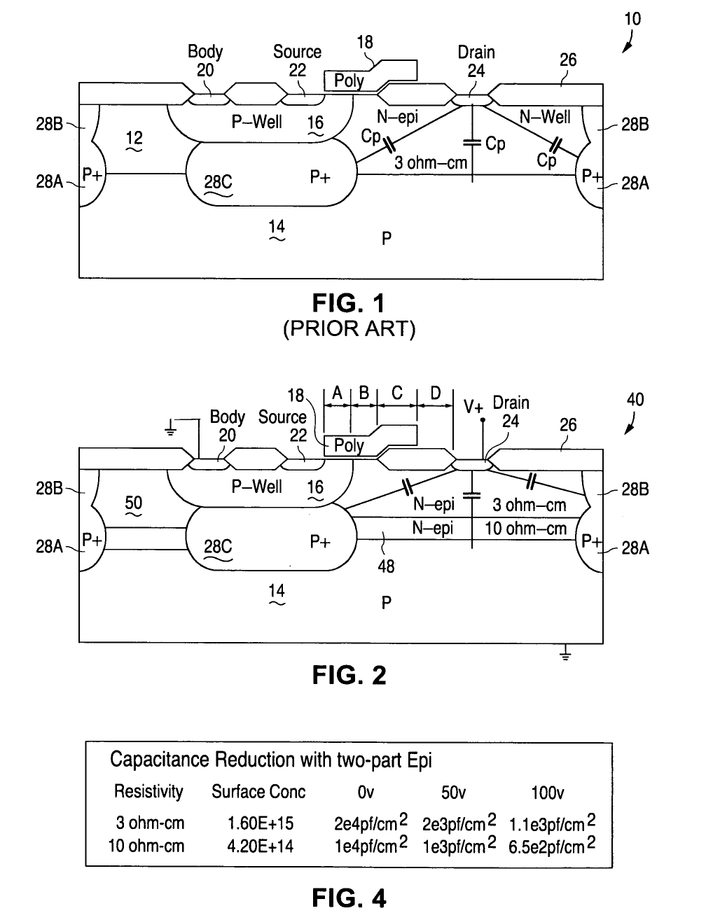

Elements identified with the same numerals may be the same or equivalent.

### DETAILED DESCRIPTION

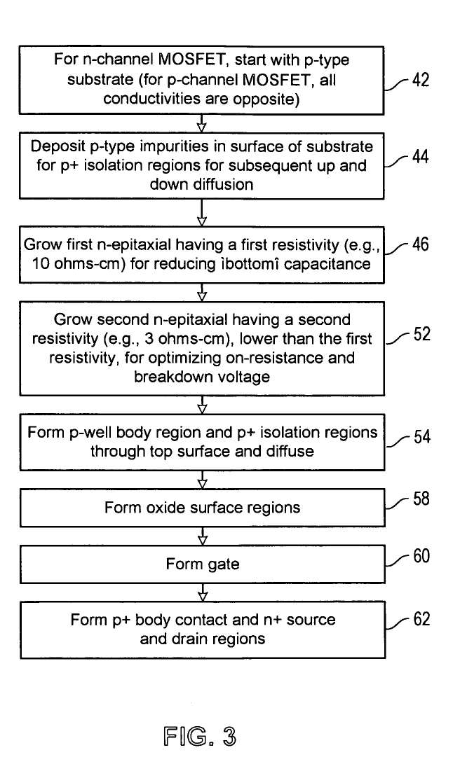

FIG. 2 illustrates a lateral DMOS transistor 40 in accordance with one embodiment of the invention. FIG. 2 will be described with reference to the flowchart of FIG. 3. The described process is for forming an n-channel transistor. For a p-channel transistor, the conductivities are reversed.

In step 42 of FIG. 3, a p-type starting silicon substrate 14 is provided. Its resistivity may be on the order of 0.01-50 ohms-cm.

In step 44, the substrate is masked using conventional techniques, and a p-type dopant, such as boron, is introduced by surface diffusion or implantation into the areas where the p+ isolation regions 28A and p+ region 28C are to be formed.

In step 46, an n-type bottom epitaxial layer 48 is grown over the substrate 14 using conventional techniques involving introducing gases into a deposition chamber and heating the substrate. The bottom epitaxial layer 48 is doped (e.g., with phosphorus or arsenic) during the formation of layer 48 to have a higher resistivity than the subsequently formed upper epitaxial layer 50. In one embodiment, the bottom epitaxial layer 48 is formed to have a resistivity of 10 ohms-cm. The optimal thickness of layer 48 and its resistivity (e.g., to achieve the lowest capacitance while not adversely affecting on-resistance and breakdown voltage) depend on the particular transistor being fabricated. In one embodiment, the thickness of layer 48 is between 0.5 and 4 microns. The thickness of layer 48 should typically be less than half the total thickness of the epitaxial layers 48 and 50, and its resistivity should typically be at least double the resistivity of the upper epitaxial layer 50.

During the growth of the bottom epitaxial layer 48, the p-type dopants in the isolation regions 28A and p+ region 28C up-diffuse and down diffuse. The bottom epitaxial layer 48 should at least intersect the portion of the p-type isolation regions 28A and p+ region 28C where the p-type dopant density is the highest, since this will reduce the parasitic capacitance at the drain region the maximum amount. The bottom epitaxial layer 48 should not extend up to the body region 16 since that may adversely affect the on-resistance or breakdown voltage of the transistor.

In step 52, once the bottom epitaxial layer 48 is the desired thickness, the flow of the dopant gas (e.g., a gas containing phosphorus or arsenic) is increased to increase the density of n-type dopants in the continuously growing epitaxial layer. The portion of the epitaxial layer with the additional dopants is the upper epitaxial layer 50. The resistivity of layer 50 in one embodiment is 3 ohms-cm, but may be any resistivity less than the resistivity of the bottom epitaxial layer 48. The optimal thickness of the upper epitaxial layer 50 depends on the particular transistor being made. In one embodiment, the total thickness of the epitaxial layers 48 and 50 is about 8.5 microns, and the thickness of the bottom epitaxial layer 48 is about 3 microns.

After the upper epitaxial layer 50 is fully formed, then, in step 54, the surface is masked and p-type dopants (e.g., boron) are introduced to form p+ isolation regions 28B, which down diffuse to contact the p+ up-diffused regions 28A to form an isolated n-type tub.

Also in step 54, a lower dose of p-type dopants are introduced to form the p-body region 16 (also referred to as a p-well). The p-body region diffuses down to contact the up-diffused p+ region 28C.

In step 58, field oxide portions 26 are created using conventional oxide growth and masking techniques to expose selected areas of the surface.

In step 60, a thin gate oxide is formed over the exposed surface and a conductive gate 18 (e.g., doped poly) is formed over an edge portion of the body region 16. The area under the gate where region 16 exists is the channel region.

In step 62, suitable p and n-type dopants (e.g, boron, phosphorus, and arsenic) are introduced into the surface to form the p+ body contact region 20, the n+ source region 22, and the n+ drain region 24.

In one embodiment, the approximate dimensions A-D shown in FIG. 2 are as follows: A (channel length)=1 micron; B=1.4 microns; C=3.6 microns; D=3.0 microns. The dimensions depend on the breakdown voltages required.

In one embodiment, the up-diffusion of the p+ isolation regions 28A and p+ region 28C is about 4.7 microns, and the down diffusion into the substrate is about 7 microns. The depth of the body region is about 3.5 microns.

The body contact region 20 and source region 22 are typically connected to ground. Typically, a terminal of a load is connected to the drain region 24, and another terminal of the load is connected to a positive voltage. Other connections for the transistor are also used. A voltage above a threshold applied to the gate inverts the channel region so as to conduct current between the source region 22 and the drain region 24 and through the load.

When the transistor is off and a positive voltage is connected to the drain region 24, a depletion region is created in the n-epitaxial layers 48/50. The depletion region has no charge carriers so basically acts as a dielectric. The drain region 24 forms parasitic capacitors with the substrate 14 and with the various p-type regions 16 and 28A-C. The parasitic capacitances each have a capacitance value that is inversely proportional to the width of the depletion regions between the drain region 24 and the substrate 14 and between the drain region 24 and p+ regions 28A-C.

Since the resistivity of the bottom epitaxial layer 48 is higher than that of the upper epitaxial layer 50 (i.e., the bottom epitaxial layer 48 has a lower dopant density), the depletion region will extend further laterally into the epitaxial layer 48, compared with the depletion region that will occur in the epitaxial layer 50. Further, regarding the parasitic capacitance between the drain region 24 and the substrate 14, the depletion region will extend deeper. Thus, the parasitic capacitance is lowered for all the parasitic capacitances that are affected by the bottom epitaxial layer 48. The capacitances that are lowered are generally referred to as the “bottom capacitance” in step 46 of FIG. 3.

For low drain voltages, relative to the rated maximum voltage of the transistor, the depletion region width is smaller, so this capacitance reduction effect is more pronounced. The maximum rated voltage is typically specified in a data sheet for the transistor and is a voltage below the breakdown voltage of the transistor.

FIG. 4 is a chart showing the capacitance value in picofarads per square centimeter for the epitaxial layers 48 and 50 as the drain voltage is increased from 0 volts to 100 volts (wider depletion region), with a grounded substrate and body region. Numbers shown assume the single-sided-step-function-approximation with regard to depletion width versus voltage. The bottom epitaxial layer 48 has a dopant surface concentration of 4.2 E+14 and a resistivity of 10 ohms-cm, while the upper epitaxial layer 50 has a dopant surface concentration of 1.6 E+15 and a resistivity of 3 ohms-cm. The capacitance per cm² of the 10 ohms-cm material is approximately half the capacitance per cm² of the 3 ohms-cm material. The capacitance values of the various parasitic capacitances in FIG. 2 depend on the thicknesses of the epitaxial layers 48 and 50 and on other factors. By increasing the thickness of the bottom epitaxial layer 48, the parasitic capacitance values are reduced.

Since the on-resistance is predominantly dependent on the characteristics of the upper portion of the upper epitaxial layer 50 where the majority of the current flows through, the higher resistivity of the bottom epitaxial layer 48 has minimal effect on the on-resistance. Since the bottom epitaxial layer 48 is formed for free, the inclusion of the bottom epitaxial layer 48 provides the benefit of faster switching speed with no adverse effects.

This technique can also be applied to lateral bipolar transistors, where the drain region 24 in FIG. 2 acts as a collector, and the body region 16 acts as a base. The characteristics and dimensions of the regions may be different for a bipolar transistor. In a bipolar transistor, there would be no gate.

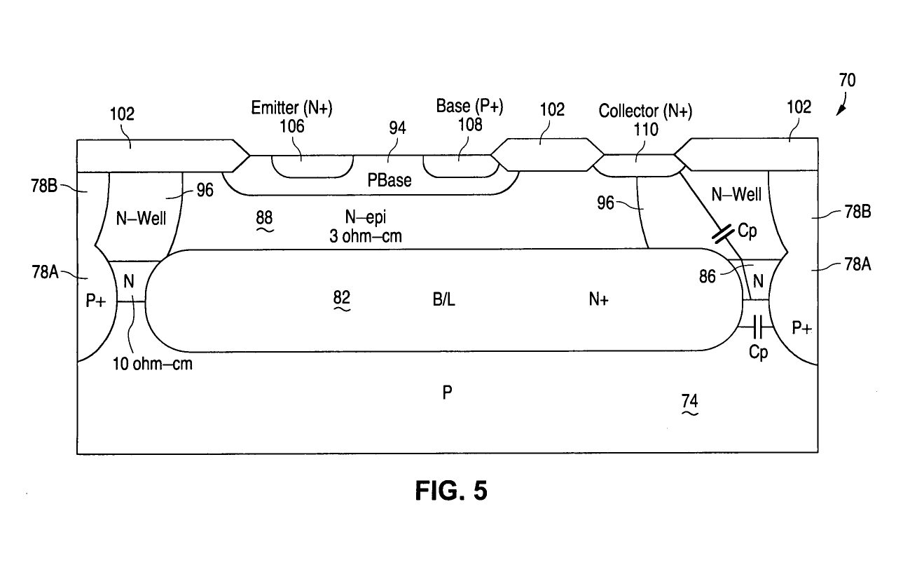

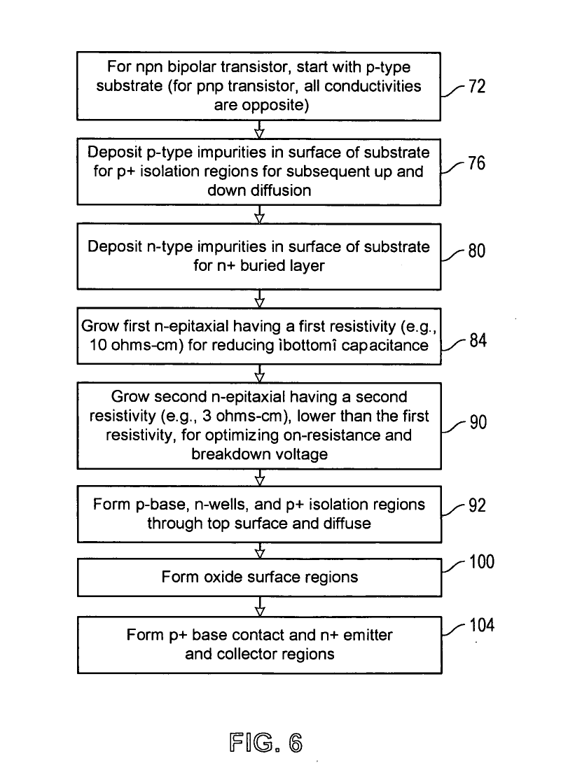

This technique is also applicable to vertical bipolar transistors, such as shown in FIG. 5. The flowchart of FIG. 6 identifies one technique for forming the npn bipolar transistor 70 of FIG. 5. For a pnp transistor, all conductivities are reversed.

In step 72 of FIG. 6, a p-type substrate 74 is provided.

In step 76, p-type dopants are implanted into the substrate 74 surface to form the p+ isolation regions 78A after up and down diffusion.

In step 80, n-type dopants are implanted to form the n+ buried layer 82. Buried layer 82 reduces the on-resistance of the transistor because the current flows laterally through the buried layer 82 to the collector. Also, the buried layer 82 reduces pnp parasitic transistor effects.

In step 84, an n-type bottom epitaxial layer 86 is formed similar to the layer 48 in FIG. 2. The bottom epitaxial layer 86 is formed to have a resistivity (e.g., 10 ohmscm) greater than that of the upper n-type epitaxial layer 88 (e.g., 3 ohms-cm) to increase the depletion region, resulting in a decrease of the “bottom capacitance” between the collector 110 and the regions 78A (laterally) and between the collector 110 and the substrate 74 (vertically). The bottom epitaxial layer 86 should preferable intersect the buried layer 82 and p+ isolation regions 78A at their highest dopant concentrations to have the greatest effect in reducing capacitance.

In step 90, the n-type upper epitaxial layer 88 is grown, similar to the layer 50 in FIG. 2. The layer 88 has a resistivity that is optimized for a low on-resistance and the desired breakdown voltage. The epitaxial layers 86/88 are formed using the same techniques described with respect to FIG. 2.

In step 92, the p-base region 94, n-wells 96, and p+ isolation regions 78B are formed using conventional techniques.

In step 100, the surface oxide regions 102 are formed.

In step 104, the n+ emitter region 106, the p+ base contact region 108, and the n+ collector contact 110 are formed using conventional techniques.

The collector contact region 110 is typically connected to a terminal of a load, and another terminal of the load is connected to a positive voltage. The substrate 74 and emitter region 106 are typically connected to ground. When the base is forward biased with respect to the emitter, a current flows between the emitter region 106 and the collector contact region 110 through the base 94 and through the combination of the buried layer 82 and the upper epitaxial layer 88.

When the transistor is off, the bottom epitaxial layer 86, being less doped than the upper epitaxial layer 88, increases the width of the depletion region and thus reduces the parasitic capacitance between the collector contact region 110 and the substrate 74 (vertical component) and between the buried layer 82 and the p+ isolation region 78A (lateral component). Preferably, the bottom epitaxial layer 86 does not extend above the buried layer 82 or else the layer 86 would adversely affect the on-resistance. In one embodiment, the buried layer 82 is up-diffused 3.5 microns, and the bottom epitaxial layer is about 2.5 microns thick. The upper epitaxial layer 88 in one embodiment is about 6 microns thick.

As with FIG. 2, the improvement in parasitic capacitance using bottom epitaxial layer 86 comes at absolutely no expense since no addition time is taken to form the bottom epitaxial layer 86.

This concept can be use in the formation of any type of lateral or vertical transistor using an epitaxial layer. For example, the technique may be applied to a vertical DMOS device or a lateral bipolar device. The concept is particularly well suited for high voltage transistors having a drift region Having described the invention in detail, those skilled in the art will appreciate that, given the present disclosure, modifications may be made to the invention without departing from the spirit and inventive concepts described herein. Therefore, it is not intended that the scope of the invention be limited to the specific embodiments illustrated and described.

What is claimed is:

1. A transistor comprising:
a semiconductor substrate of a first conductivity type, the substrate having a first surface;
a bottom epitaxial layer of a second conductivity type formed directly over the first surface, the bottom epitaxial layer being doped with dopants of the second conductivity type so as to have a first resistivity;
an upper epitaxial layer of the second conductivity type formed directly over the bottom epitaxial layer, the upper epitaxial layer being doped with dopants of the second conductivity type so as to have a second resistivity lower than the first resistivity;
a well region of the first conductivity type formed in the upper epitaxial layer;
a current carrying first region of the second conductivity type formed in the well region; and
a current carrying second region of the second conductivity type formed in the upper epitaxial layer and outside of the well region,
wherein a depletion region is created that extends down into the bottom epitaxial layer when a voltage above a certain voltage is applied to the second region.

2. The transistor of claim 1 wherein the first region is an emitter region, the second region is a collector region, and the well region is a base region.

3. The transistor of claim 1 wherein the first region is a source region, the second region is a drain region, and the well region is a body region, the transistor further comprising a gate overlying and insulated from the body region to create a conductive channel of the second conductivity type in the body region when a voltage greater than a threshold voltage is applied to the gate.

4. The transistor of claim 3 further comprising a third region of the first conductivity type formed in the bottom epitaxial layer and at least a portion of the upper epitaxial layer, the third region directly contacting the substrate and the body region.

5. The transistor of claim 4 wherein a thickness of the bottom epitaxial layer is less than a thickness of the third region above the substrate.

6. The transistor of claim 4 wherein the bottom epitaxial layer intersects the third region in an area of highest dopant concentration in the third region.

7. The transistor of claim 6 further comprising isolation regions of the first conductivity type extending from a surface of the upper epitaxial layer to the substrate.

8. The transistor of claim 1 wherein the certain voltage is below a maximum rated voltage of the transistor.

9. The transistor of claim 1 wherein the bottom epitaxial layer decreases a parasitic capacitance between the second region and the substrate without adversely affecting on-resistance of the transistor.

10. The transistor of claim 1 wherein the first resistivity is more than double the second resistivity.

11. The transistor of claim 1 wherein the first resistivity is more than three times the second resistivity.

12. The transistor of claim 1 wherein the first resistivity is approximately 10 ohms-cm and the second resistivity is approximately 3 ohms-cm.

13. The transistor of claim 1 wherein the first region is an emitter region, the second region is a collector region, and the well region is a base region, the transistor further comprising a third region of the first conductivity type formed in the bottom epitaxial layer and at least a portion of the upper epitaxial layer, the third region directly contacting the substrate.

14. The transistor of claim 13 wherein a thickness of the bottom epitaxial layer is less than a thickness of the third region above the substrate.

15. The transistor of claim 13 wherein the bottom epitaxial layer intersects the third region in an area of highest dopant concentration in the third region.

16. The transistor of claim 15 further comprising isolation regions of the first conductivity type extending from a surface of the upper epitaxial layer to the substrate.

17. The transistor of claim 1 wherein the transistor is a lateral transistor.

18. The transistor of claim 17 wherein the transistor is a bipolar transistor.

19. The transistor of claim 17 wherein the transistor is a DMOS transistor.

20. The transistor of claim 1 wherein the transistor is a vertical transistor.

21. The transistor of claim 20 wherein the transistor is a bipolar transistor.

22. The transistor of claim 20 wherein the transistor is a DMOS transistor.

23. A method of forming a transistor comprising:
providing a semiconductor substrate of a first conductivity type having a first surface;
growing a bottom epitaxial layer of a second conductivity type directly over the first surface, the bottom epitaxial layer being doped with dopants of the second conductivity type so as to have a first resistivity;
growing an upper epitaxial layer of the second conductivity type directly over the bottom epitaxial layer, the upper epitaxial layer being doped with dopants of the second conductivity type so as to have a second resistivity lower than the first resistivity;
forming a well region of the first conductivity type in the upper epitaxial layer;
forming a current carrying first region of the second conductivity type in the well region; and
forming a current carrying second region of the second conductivity type in the upper epitaxial layer and outside of the well region,
the characteristics of the upper epitaxial layer and bottom epitaxial layer being such that a depletion region is created that extends down into the bottom epitaxial layer when a voltage above a certain voltage is applied to the second region.

24. The method of claim 23 wherein the first region is a source region, the second region is a drain region, and the well region is a body region, the method further comprising forming a third region of the first conductivity type in the bottom epitaxial layer and at least a portion of the upper epitaxial layer, the third region directly contacting the substrate and the body region.

25. The method of claim 24 wherein a thickness of the bottom epitaxial layer is less than a thickness of the third region above the substrate, and wherein the bottom epitaxial layer intersects the third region in an area of highest dopant concentration in the third region.

26. The method of claim 23 wherein the bottom epitaxial layer decreases a parasitic capacitance between the second region and the substrate without adversely affecting on-resistance of the transistor.

27. The method of claim 23 wherein the first resistivity is more than double the second resistivity.

28. The method of claim 23 wherein the first resistivity is more than three times the second resistivity.

29. The method of claim 23 wherein the first resistivity is approximately 10 ohms-cm and the second resistivity is approximately 3 ohms-cm.

30. The method of claim 23 wherein the first region is an emitter region, the second region is a collector region, and the well region is a base region, the method further comprising forming a third region of the first conductivity type in the bottom epitaxial layer and at least a portion of the upper epitaxial layer, the third region directly contacting the substrate,
wherein a thickness of the bottom epitaxial layer is less than a thickness of the third region above the substrate, and wherein the bottom epitaxial layer intersects the third region in an area of highest dopant concentration in the third region.

31. The method of claim 23 wherein the transistor is a lateral transistor.

32. The transistor of claim 23 wherein the transistor is a vertical transistor.
